(19) United States
(12) Patent Application Publication
(10) Pub. No.: US 2012/0100793 A1
(43) Pub. Date: Apr. 26, 2012

(54) CONTAINER DATA CENTER

(75) Inventor: YAO-TING CHANG, Tu-Cheng (TW)

(73) Assignee: HON HAI PRECISION INDUSTRY CO., LTD., Tu-Cheng (TW)

(21) Appl. No.: 12/940,040

(22) Filed: Nov. 4, 2010

(30) Foreign Application Priority Data
Oct. 21, 2010 (TW) 99135879

(51) Int. Cl. H05K 5/00

(52) U.S. Cl. 454/184

(57) ABSTRACT

A container data center includes a housing for arranging servers therein, and an air purifier. The air purifier includes a hollow filtering barrel, an air outlet pipe connected between the filtering barrel and the housing, and an exhaust fan. The exhaust fan draws air from the filtering barrel through the air outlet pipe and exhausts air into the housing.

### BACKGROUND

1. Technical Field

The present disclosure relates to container data centers, and more particularly, to a container data center with an air purifier.

2. Description of Related Art

At present, racks of servers and storage devices are arranged in a container, together with relevant equipment, to form a portable data center. The servers and storage devices consume electrical power and generate large amounts of heat during operation. The heat collectively generated in the densely-packed racks can have adverse effects on the performance, reliability and useful life of the equipment in the racks. Accordingly, air conditioners having air purifiers are often used in portable data centers. However, filtering materials such as gauze and filter paper are often used in the air purifiers, which is resource consuming.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of a first exemplary embodiment of a container data center, including an air purifier.

FIG. 2 is a partial top schematic view of the air purifier of FIG. 1.

FIG. 3 is a schematic view of a second exemplary embodiment of a container data center.

FIG. 4 is a schematic view of a third exemplary embodiment of a container data center.

FIG. 5 is a schematic view of a fourth exemplary embodiment of a container data center.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

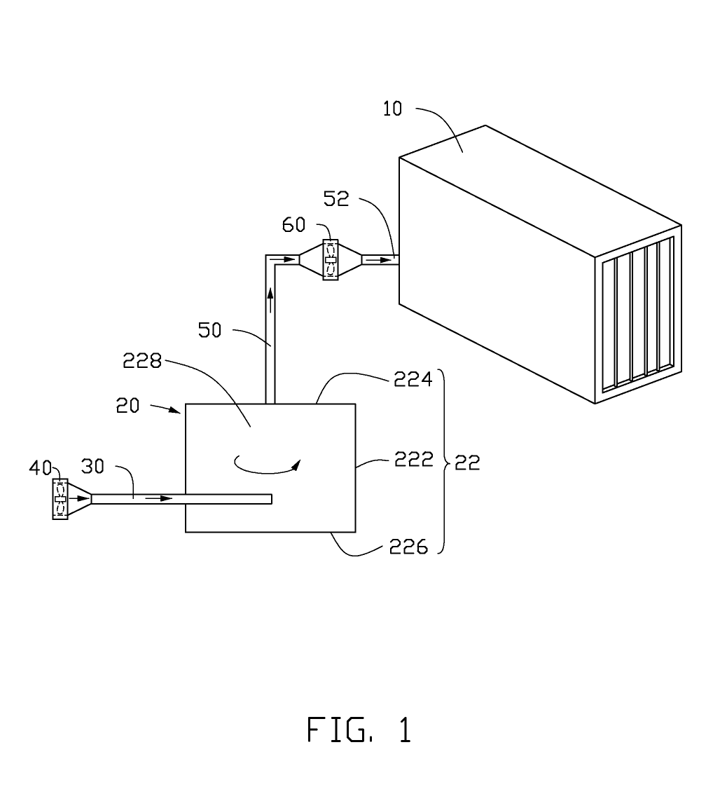

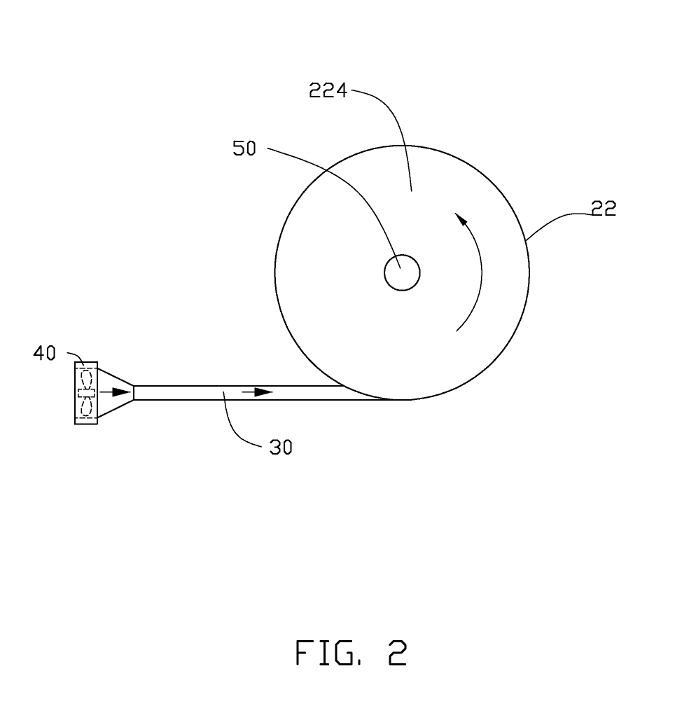

Referring to FIGS. 1 and 2, a container data center 1 in accordance with a first exemplary embodiment includes a portable housing 10 and an air purifier 20 attached to the housing 10.

In the embodiment, the housing 10 is a standard container, which is used to receive various electronic devices and relevant equipment, such as servers, storage devices, monitoring instruments.

Referring to FIG. 2, the air purifier 20 includes a hollow cylinder-shaped filtering barrel 22, an air inlet pipe 30 connected to the filtering barrel 22, an air blower 40 connected to the air inlet pipe 30, an air outlet pipe 50 connected between the filtering barrel 22 and the housing 10, and an exhaust fan 60 for exhausting purified air from the filtering barrel 22 into the housing 10 through the air outlet pipe 50. The filtering barrel 22 includes a circular peripheral wall 222, and a top board 224 and a bottom board 226 respectively positioned at a top end and a bottom end of the peripheral wall 222. An air chamber 228 is enclosed by the peripheral wall 222 and the top and bottom boards 224 and 226. The air inlet pipe 30 is connected to the peripheral wall 222 along a direction tangent to the peripheral wall 222, and is positioned adjacent to the bottom end of the peripheral wall 222. The air inlet pipe 30 is in communication with the air chamber 228 of the filtering barrel 22. The air outlet pipe 50 is connected to a center of the top board 224, and is in communication with the air chamber 228 of the filtering barrel 22.

In the embodiment, the air blower 40 and the exhaust fan 60 are of axial type. The exhaust fan 60 is connected to the air outlet pipe 50 adjacent to the housing 10.

In use, the air blower 40 and the exhaust fan 60 are turned on, and air in the environment is drawn into the air inlet pipe 30 by the air blower 40. Meanwhile, the exhaust fan 60 draws air in the filtering barrel 22 through the air outlet pipe 50, thereby generating a negative pressure in the filtering barrel 22. Thus, the air in the air inlet pipe 30 quickly flows into the filtering barrel 22 along the peripheral wall 222, which causes eddy currents in the filtering barrel 20. Dust, moisture, and other impurities are separated from the air due to centrifugal force and gravity, and fall along an inner side of the peripheral wall 222 to be collected on the bottom board 226 of the filtering barrel 22. Purified air flows toward a center of the filtering barrel 22, and rises toward the top board 224 to flow into the air outlet pipe 50. The purified air in the air outlet pipe 50 is drawn by the exhaust fan 60 to quickly flow into the housing 10 to cool the electronic devices. The dust, moisture, and other impurities on the bottom board 226 of the filtering barrel 22 can be cleared. Because there are no use of filtering materials such as gauze and filter paper in the air purifier 20, the air purifier 20 is a low-carbon, and environmentally-friendly equipment.

In other embodiments, the exhaust fan 60 may be mounted in the housing 10 and in communication with an exhaust port 52 of the air outlet pipe 50. The air blower 40 and the exhaust fan 60 may be of centrifugal type.

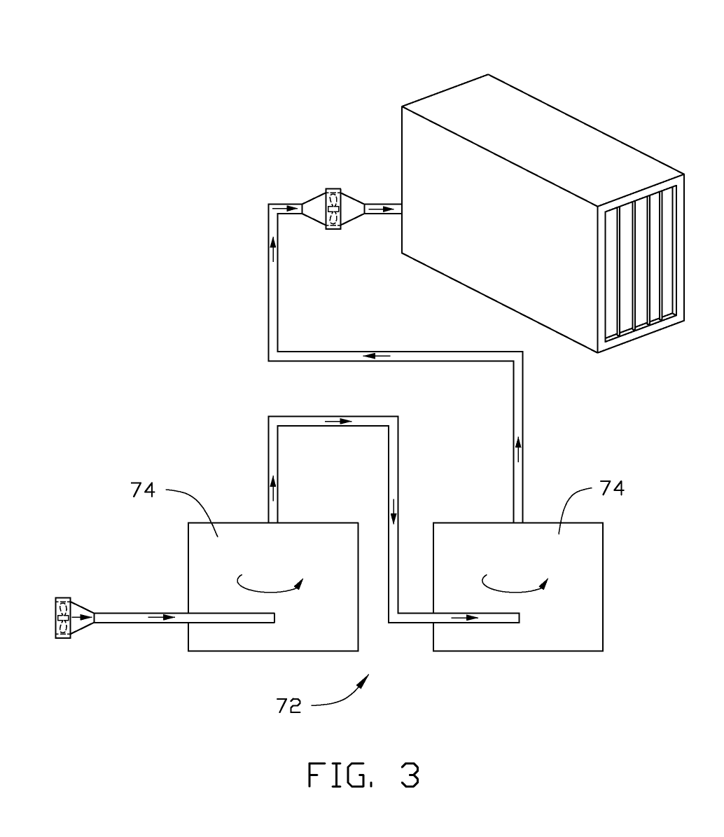

Referring to FIG. 3, in a second exemplary embodiment, an air purifier 72 includes two filtering barrels 74 connected in series to meet higher requirements of air purity. In other embodiments, the air purifier 72 may include more than two filtering barrels 74 connected in series.

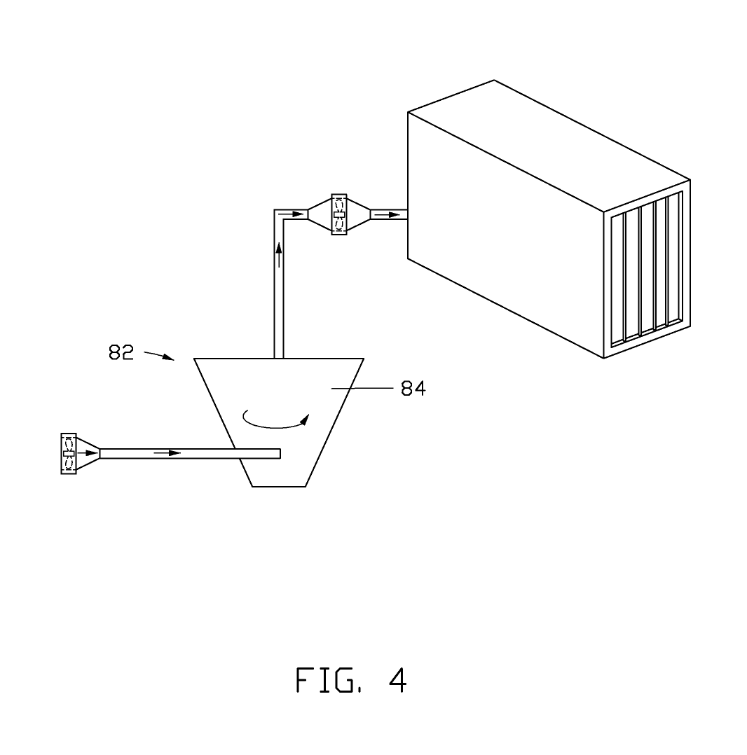

Referring to FIG. 4, in a third exemplary embodiment, a filtering barrel 84 of an air purifier 82 is hollow truncated cone-shaped instead of hollow cylinder-shaped, which is shown in a first exemplary embodiment of the container data center.

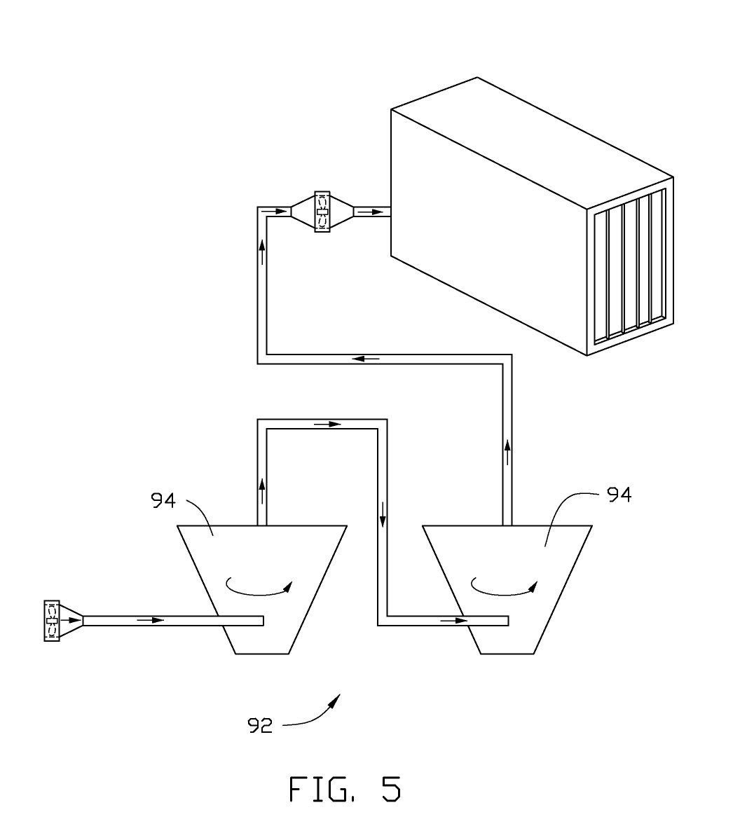

Referring to FIG. 5, in a fourth exemplary embodiment, an air purifier 92 includes two hollow truncated cone-shaped filtering barrels 94 connected in series. In other embodiments, the air purifier 92 may include more than two hollow truncated cone-shaped filtering barrels 94 connected in series.

It is to be understood, however, that even though numerous characteristics and advantages have been set forth in the foregoing description of embodiments, together with details of the structures and functions of the embodiments, the present disclosure is illustrative only and changes may be made in detail, especially in matters of shape, size, and arrangement of parts within the principles of the present disclosure to the full extent indicated by the broad general meaning of the terms in which the appended claims are expressed.

What is claimed is:

1. A container data center comprising:
a housing configured for arranging servers; and
an air purifier comprising a hollow filtering barrel, an air outlet pipe connected between the filtering barrel and the housing, and an exhaust fan for exhausting air from the filtering barrel into the housing through the air outlet pipe.

2. The container data center of claim 1, wherein the air purifier further comprises an air inlet pipe connected to the filtering barrel, and an air blower connected to the air inlet pipe.

3. The container data center of claim 2, wherein the filtering barrel comprises a circular peripheral wall, and two boards respectively positioned at opposite ends of the peripheral wall; and the air inlet pipe is connected to the peripheral wall along a direction tangent to the peripheral wall.

4. The container data center of claim 3, wherein the air inlet pipe is positioned adjacent to one of the ends of the peripheral wall.

5. The container data center of claim 4, wherein the air outlet pipe is connected to one of the two boards adjacent to the other end of the ends of the peripheral wall.

6. The container data center of claim 5, wherein an air chamber is enclosed by the peripheral wall and the two boards of the filtering barrel, and the air inlet pipe and the air outlet pipe are in communication with the air chamber.

7. The container data center of claim 1, wherein the exhaust fan is connected to the air outlet pipe.

8. The container data center of claim 1, wherein the exhaust fan is mounted in the housing and in communication with an exhaust port of the air outlet pipe.

9. The container data center of claim 1, wherein the air blower and the exhaust fan are of axial type.

10. The container data center of claim 1, wherein the air blower and the exhaust fan are of centrifugal type.

10. The container data center of claim 1, wherein the housing is a standard container.

11. A data center comprising:
a container housing electronic devices; and
an air purifier comprising a filtering barrel, an air outlet pipe connected between the filtering barrel and the container, and an exhaust fan for exhausting air from the filtering barrel into the container through the air outlet pipe;
wherein air is purified mainly due to centrifugal force generated in the air purified before flowing into the container.

12. The data center of claim 11, wherein the filtering barrel comprises a circular peripheral wall, and two boards respectively positioned at opposite ends of the peripheral wall; and the air inlet pipe is connected to the peripheral wall along a direction tangent to the peripheral wall.

13. The data center of claim 12, wherein the air purifier further comprises an air inlet pipe connected to the peripheral wall adjacent to one of the ends of the peripheral wall, and an air blower connected to the air inlet pipe.

14. The data center of claim 13, wherein the air outlet pipe is connected to one of the two boards adjacent to the other end of the ends of the peripheral wall.

15. The data center of claim 13, wherein an air chamber is enclosed by the peripheral wall and the two boards of the filtering barrel, and the air inlet pipe and the air outlet pipe are in communication with the air chamber.
